(19) United States
(12) Patent Application Publication
(10) Pub. No.: US 2026/0293530 A1
(43) Pub. Date: Sep. 24, 2026

(54) Acoustic Devices And Methods Of Fabrication

(71) Applicant: Sonocharge Energy, Inc, Mountain View, CA (US)

(72) Inventors: William CONNACHER, Mountain View, CA (US); An HUANG, Mountain View, CA (US); Haodong LIU, Mountain View, CA (US)

(21) Appl. No.: 19/678,897

(22) Filed: May 15, 2026

Related U.S. Application Data
(63) Continuation of application No. PCT/US24/57399, filed on Nov. 26, 2024.
(60) Provisional application No. 63/602,819, filed on Nov. 27, 2023.

(51) Int. Cl. H10N 30/87; H10N 30/06

(52) U.S. Cl. CPC H10N 30/875; H10N 30/06

(57) ABSTRACT

In one aspect, the present disclosure provides an acoustic device comprising: a piezoelectric substrate; and a multi-layer metallic stack comprising a bonding layer, a conduction layer, and a cap layer, wherein the bonding layer is configured to facilitate bonding of the conduction layer to the piezoelectric substrate, and the cap layer is configured to facilitate soldering of the acoustic device to an electrical circuit.

### CROSS REFERENCE

This application is a continuation of PCT/US 2024/0573 99, filed 2024-11-26, which claims the benefit of US Provisional Application No. 63/602,819, filed 2023-11-27, both of which are entirely incorporated herein by reference.

### BACKGROUND

Traditional electrochemical cells often suffer from impedance-related issues, which can lead to reduced efficiency and compromised cell longevity. One primary culprit behind this impedance may be the uneven availability of cations and anions, which may cause suboptimal ionic concentration gradients and an inconsistent electrode surface potential. Such irregularities can hinder mass transport, diminish kinetic rates, and lead to concentration polarization effects, adversely affecting the overall performance of the electrochemical cell.

### SUMMARY

In an aspect, the present disclosure provides an acoustic device comprising: a piezoelectric substrate; and a multi-layer metallic stack comprising a bonding layer, a conduction layer, and a cap layer, wherein the bonding layer is configured to facilitate bonding of the conduction layer to the piezoelectric substrate, and the cap layer is configured to facilitate soldering of the acoustic device to an electrical circuit.

In some embodiments of any one of the acoustic devices disclosed herein, the multi-layer metallic stack further comprises a barrier layer. In some embodiments of any one of the acoustic devices disclosed herein, the barrier layer is configured to prevent diffusion between the conduction layer and the cap layer. In some embodiments of any one of the acoustic devices disclosed herein, the barrier layer is between the conduction layer and the cap layer. In some embodiments of any one of the acoustic devices disclosed herein, the bonding layer and the cap layer are disposed on opposite surfaces of the conduction layer. In some embodiments of any one of the acoustic devices disclosed herein, the conduction layer is between the bonding layer and the cap layer. In some embodiments of any one of the acoustic devices disclosed herein, the bonding layer is located closer to the piezoelectric substrate than the cap layer. In some embodiments of any one of the acoustic devices disclosed herein, the cap layer is located further away from the piezoelectric substrate than the bonding layer. In some embodiments of any one of the acoustic devices disclosed herein, the piezoelectric substrate comprises lithium niobate. In some embodiments of any one of the acoustic devices disclosed herein, the piezoelectric substrate comprises chemically reduced lithium niobate. In some embodiments of any one of the acoustic devices disclosed herein, the lithium niobate has a 128° YZ cut orientation. In some embodiments of any one of the acoustic devices disclosed herein, each of the bonding layer, the conduction layer, and the cap layer comprises a different metal or metal alloy. In some embodiments of any one of the acoustic devices disclosed herein, the conduction layer has a density of about 1000 kg/m³ to about 5000 kg/m³ and a conductivity of about 25×10⁶ S/m to about 60×10⁶ S/m. In some embodiments of any one of the acoustic devices disclosed herein, the cap layer has a higher solderability or ease of solderability than the conduction layer. In some embodiments of any one of the acoustic devices disclosed herein, the bonding layer is configured to serve as an adhesion layer between the piezoelectric substrate and the conduction layer. In some embodiments of any one of the acoustic devices disclosed herein, the conduction layer does not have an oxide layer. In some embodiments of any one of the acoustic devices disclosed herein, the conduction layer is non-oxidized. In some embodiments of any one of the acoustic devices disclosed herein, the conduction layer comprises aluminum or an aluminum-based alloy. In some embodiments of any one of the acoustic devices disclosed herein, the bonding layer comprises titanium, chromium, or a tungsten-based alloy. In some embodiments of any one of the acoustic devices disclosed herein, the cap layer comprises copper, nickel, gold, tin, or an alloy comprising any combination of the foregoing. In some embodiments of any one of the acoustic devices disclosed herein, the conduction layer is thicker than the bonding layer or the cap layer. In some embodiments of any one of the acoustic devices disclosed herein, the cap layer is thicker than the bonding layer. In some embodiments of any one of the acoustic devices disclosed herein, the conduction layer is thicker than the cap layer, and the cap layer is thicker than the bonding layer. In some embodiments of any one of the acoustic devices disclosed herein, the bonding layer is about 1 nanometer (nm) to about 5 nm. In some embodiments of any one of the acoustic devices disclosed herein, the conduction layer is about 300 nm to about 2000 nm. In some embodiments of any one of the acoustic devices disclosed herein, the cap layer is about 30 nm to about 150 nm. In some embodiments of any one of the acoustic devices disclosed herein, the piezoelectric substrate is thicker than the multi-layer metallic stack. In some embodiments of any one of the acoustic devices disclosed herein, the piezoelectric substrate is about 200 micrometers (μm) to about 1000 μm. In some embodiments of any one of the acoustic devices disclosed herein, the multi-layer metallic stack is formed via a single vacuum process comprising sputter deposition or electron beam deposition. In some embodiments of any one of the acoustic devices disclosed herein, the bonding layer, the conduction layer, and the cap layer are sputtered sequentially via the single vacuum process. In some embodiments of any one of the acoustic devices disclosed herein, the multi-layer metallic stack is formed via a plurality of vacuum processes comprising one or more plasma etch or laser ablation cleaning steps prior to a series of deposition steps, wherein the series of deposition steps is performed using pulsed laser deposition, electron beam deposition, or sputtering.

In an aspect, the present disclosure provides an acoustic module comprising: the acoustic device and the electrical circuit of any one of the acoustic devices and electrical circuits disclosed herein; and one or more solder interconnects configured to electromechanically couple the acoustic device to the electrical circuit.

In some embodiments of any one of the acoustic modules disclosed herein, the electrical circuit comprises a flexible printed circuit. In some embodiments of any one of the acoustic modules disclosed herein, the flexible printed circuit comprises copper traces printed on polyamide. In some embodiments of any one of the acoustic modules disclosed herein, the electrical circuit comprises a printed circuit board. In some embodiments of any one of the acoustic modules disclosed herein, the one or more solder interconnects comprises a lead-free solder. In some embodiments of any one of the acoustic modules disclosed herein, the lead-free solder comprises SAC 305. In some embodiments of any one of the acoustic modules disclosed herein, the lead-free solder is initially applied to the electrical circuit using a stencil. In some embodiments of any one of the acoustic modules disclosed herein, one or more solder interconnects are formed using a reflow process, to thereby electromechanically couple the acoustic device to the electrical circuit. In some embodiments of any one of the acoustic modules disclosed herein, the height of one or more solder interconnects is about 25 μm to about 75 μm. In some embodiments of any one of the acoustic modules disclosed herein, the one or more solder interconnects comprise a plurality of solder interconnects having a substantially uniform height or thickness.

In an aspect, the present disclosure provides a method of forming an acoustic device, comprising: providing a piezoelectric substrate; and forming a multi-layer metallic stack on the piezoelectric substrate, wherein the forming of the multi-layer metallic stack comprises sequentially depositing a bonding layer, a conduction layer, and a cap layer within a single vacuum process. In some embodiments of any one of the methods disclosed herein, the bonding layer, the conduction layer, and the cap layer are sequentially deposited using a sputtering process.

In an aspect, the present disclosure provides a method of forming an acoustic module, comprising: applying a solder to an electrical circuit; aligning and placing the acoustic device of any one of the acoustic devices disclosed herein onto the electrical circuit; and using a thermal reflow process to form one or more solder interconnects that electromechanically couple the acoustic device to the electrical circuit. In some embodiments of any one of the methods disclosed herein, the solder is applied to the electrical circuit using a stencil.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the disclosure are set forth with particularity in the appended claims. A better understanding of the features and advantages of the present disclosure will be obtained by reference to the following detailed description that sets forth illustrative embodiments, in which the principles of the disclosure are utilized, and the accompanying drawings, of which:

FIG. 1 shows an exemplary cross-sectional view of an acoustic device, according to some embodiments of the disclosure;

FIG. 2A shows an acoustic device operably coupled to an electrochemical device or cell, according to some embodiments of the disclosure;

FIG. 2B shows a configuration of an electrochemical cell and an acoustic device coupled to an interior of the electrochemical cell, according to some embodiments of the disclosure;

FIG. 2C shows a configuration of an electrochemical cell and an acoustic device coupled to the exterior of the electrochemical cell, according to some embodiments of the disclosure;

FIGS. 3A-3D show exemplary configurations of an acoustic device coupled to an electrochemical cell, according to some embodiments of the disclosure;

FIG. 4A shows an example of a plurality of acoustic devices coupled to an interior of a device comprising a plurality of electrochemical cells, according to some embodiments of the disclosure;

FIG. 4B shows an example of a plurality of acoustic devices coupled to an exterior of a device comprising a plurality of electrochemical cells, according to some embodiments of the disclosure;

FIG. 5 shows a computer system in communication with the acoustic devices and/or electrochemical cell, according to some embodiments of the disclosure;

FIGS. 6A-6C show cross-sectional views of an exemplary acoustic device during the fabrication process, according to some embodiments of the disclosure; and

FIG. 6D shows a cross-sectional view of an exemplary acoustic device that has been soldered to a printed circuit, according to some embodiments of the disclosure.

### DETAILED DESCRIPTION

Provided herein are acoustic devices that can improve the performance and lifetime of an electrochemical device. The electrochemical device can comprise one or more electrochemical cells. The acoustic device can generate and transmit acoustic waves that can enhance the mobilization and movement of mobile species, e.g., cations and/or anions. The enhanced mobilization and movement of mobile species can lead to better distribution of the mobile species within the electrochemical cell. In some embodiments, mobile species, e.g., cations and/or anions, can be evenly available throughout the electrochemical cell. In some embodiments, the acoustic waves can modulate the ionic concentration gradient for a more uniform distribution of the mobile species and prevent concentration polarization. This ensures a more consistent flow of current through the electrochemical cell, enhancing overall efficiency.

In some embodiments, the present disclosure provides an acoustic device comprising: a piezoelectric substrate and a multi-layer metallic stack. In some embodiments, the multi-layer metallic stack may comprise a bonding layer, a conduction layer, and a cap layer. In some embodiments, the bonding layer may be configured to facilitate bonding of the conduction layer to the piezoelectric substrate. In some embodiments, the cap layer may be configured to facilitate the soldering of the acoustic device to an electrical circuit.

In some embodiments, each of the bonding layer, the conduction layer, and the cap layer may comprise a different metal or metal alloy.

In some embodiments, the multi-layer metallic stack can further comprise a barrier layer. In some embodiments, the barrier layer can be disposed between the conduction and the cap layers. In some embodiments, the barrier layer can be configured to prevent diffusion between these two layers. In some embodiments, the barrier layer can prevent the conduction and cap layers from producing brittle intermetallic compounds over time that can fracture the cap layer. In some embodiments, the barrier layer can comprise tungsten, titanium, nickel, nickel-phosphorous, vanadium, chromium, or molybdenum, or a combination thereof. In some embodiments, the barrier layer can comprise 90% tungsten/ 10% titanium. In some embodiments, the barrier layer can have a thickness from about 0.5 nm to about 1 nm, from about 0.5 nm to about 2 nm, from about 0.5 nm to about 5 nm, from about 0.5 nm to about 10 nm, from about 0.5 nm to about 20 nm, from about 1 nm to about 2 nm, from about 1 nm to about 5 nm, from about 1 nm to about 10 nm, from about 1 nm to about 20 nm, from about 2 nm to about 5 nm, from about 2 nm to about 10 nm, from about 2 nm to about 20 nm, from about 5 nm to about 10 nm, from about 5 nm to about 20 nm, or from about 10 nm to about 20 nm. In some embodiments, the barrier layer can have a thickness of at least about 0.5 nm, at least about 1 nm, at least about 2 nm, at least about 5 nm, at least about 10 nm, or at least about 20 nm. In some embodiments, the barrier layer can have a thickness of at most about 20 nm, at most about 10 nm, at most about 5 nm, at most about 2 nm, at most about 1 nm, or at most about 0.5 nm.

In some embodiments, the conduction layer can be thicker than the cap layer. In some embodiments, the cap layer can be thicker than the bonding layer.

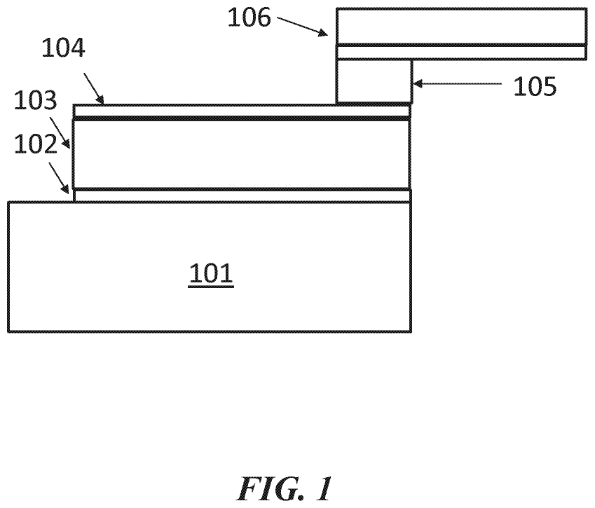

FIG. 1 shows an exemplary cross-sectional view of an acoustic device. The acoustic device comprises a substrate 101, a bonding layer 102, a conduction layer 103, and a cap layer 104. In some embodiments, the acoustic device can be connected to a printed circuit 106 (e.g., a flexible printed circuit) through a layer of electromechanical interconnect 105 (e.g., solder paste).

### Conduction Layer

In some embodiments, the multi-layer metallic stack may comprise a conduction layer (e.g., 103 of FIG. 1) configured to transmit electric signals to the piezoelectric substrate.

In some embodiments, the conduction layer can comprise a metal or a metal alloy. The composition of the conduction layer may be selected to have a relatively low density and high conductivity. Metal that is too dense can change the intended frequency of generated acoustic waves, which can reduce the efficiency of the acoustic waves. Metal that is too resistive can cause excess ohmic heating. Aluminum is a metal with low density and high conductivity. In some embodiments, the conduction layer can comprise aluminum or an aluminum-based alloy. In some embodiments, the aluminum-based alloy can comprise a metal selected from copper, magnesium, manganese, silicon, tin, nickel, or zinc, or combinations thereof.

In some embodiments, the conduction layer can have a density from about 500 kilogram/cubic meter (kg/m³) to about 1000 kg/m³, from about 500 kg/m³ to about 2000 kg/m³, from about 500 kg/m³ to about 3000 kg/m³, from about 500 kg/m³ to about 4000 kg/m³, from about 500 kg/m³ to about 5000 kg/m³, from about 500 kg/m³ to about 10000 kg/m³, from about 1000 kg/m³ to about 2000 kg/m³, from about 1000 kg/m³ to about 3000 kg/m³, from about 1000 kg/m³ to about 4000 kg/m³, from about 1000 kg/m³ to about 5000 kg/m³, from about 1000 kg/m³ to about 10000 kg/m³, from about 2000 kg/m³ to about 3000 kg/m³, from about 2000 kg/m³ to about 4000 kg/m³, from about 2000 kg/m³ to about 5000 kg/m³, from about 2000 kg/m³ to about 10000 kg/m³, from about 3000 kg/m³ to about 4000 kg/m³, from about 3000 kg/m³ to about 5000 kg/m³, from about 3000 kg/m³ to about 10000 kg/m³, from about 4000 kg/m³ to about 5000 kg/m³, from about 4000 kg/m³ to about 10000 kg/m³, or from about 5000 kg/m³ to about 10000 kg/m³.

In some embodiments, the conduction layer can have a conductivity from about 10×10⁶ siemens per meter (S/m) to about 20×10⁶ S/m, from about 10×10⁶ S/m to about 25×10⁶ S/m, from about 10×10⁶ S/m to about 30×10⁶ S/m, from about 10×10⁶ S/m to about 50×10⁶ S/m, from about 10×10⁶ S/m to about 100×10⁶ S/m, from about 20×10⁶ S/m to about 25×10⁶ S/m, from about 20×10⁶ S/m to about 30×10⁶ S/m, from about 20×10⁶ S/m to about 50×10⁶ S/m, from about 20×10⁶ S/m to about 100×10⁶ S/m, from about 25×10⁶ S/m to about 30×10⁶ S/m, from about 25×10⁶ S/m to about 50×10⁶ S/m, from about 25×10⁶ S/m to about 100×10⁶ S/m, from about 30×10⁶ S/m to about 50×10⁶ S/m, from about 30×10⁶ S/m to about 100×10⁶ S/m, or from about 50×10⁶ S/m to about 100×10⁶ S/m.

In some embodiments, the conduction layer can have a thickness from about 300 nanometers (nm) to about 500 nm, from about 300 nm to about 1000 nm, from about 300 nm to about 1500 nm, from about 300 nm to about 2000 nm, from about 300 nm to about 5000 nm, from about 500 nm to about 1000 nm, from about 500 nm to about 1500 nm, from about 500 nm to about 2000 nm, from about 500 nm to about 5000 nm, from about 1000 nm to about 1500 nm, from about 1000 nm to about 2000 nm, from about 1000 nm to about 5000 nm, from about 1500 nm to about 2000 nm, from about 1500 nm to about 5000 nm, or from about 2000 nm to about 5000 nm.

In some embodiments, the conduction layer can be non-oxidized. In some embodiments, the conduction layer may not have an oxide layer. In some embodiments, oxidized metal or oxidized metal alloy, e.g., partially oxidized metal or alloy, may reduce the conductivity of the conduction layer and/or reduce the solderability of the conduction layer. In some embodiments, a cap layer can be deposited on top of the conduction layer to prevent the oxidation of the conduction layer and/or improve the solderability of the conduction layer.

In some embodiments, the conduction layer can be disposed between the bonding layer and the cap layer. In some embodiments, the conduction layer can be disposed directly in contact with an adjacent layer. In some embodiments, the conduction layer can be thicker than the bonding layer and/or the cap layer. In some embodiments, the conduction layer can be at least about 10%, at least about 20%, at least about 50%, at least about 100%, at least about 150%, at least about 200%, at least about 300%, at least about 400%, at least 500%, or more, thicker than the bonding layer and/or the cap layer.

### Bonding Layer

In some embodiments, the multi-layer metallic stack may comprise a bonding layer (e.g., 102 of FIG. 1) configured to serve as an adhesion layer between the piezoelectric substrate and the conduction layer.

In some embodiments, the conduction layer may comprise a composition that may not have good adhesion to the piezoelectric substrate. In some embodiments, an adhesion or bonding layer can be formed prior to the deposition of the conduction layer with a reactive metal that can form a chemical bond with polar atoms on the surface of the piezoelectric substrate. In some embodiments, the bonding layer can be deposited immediately prior to the conduction layer without breaking the vacuum so that the surface of the bonding layer may not oxidize.

In some embodiments, the bonding layer can be located closer to the piezoelectric substrate than the cap layer. In some embodiments, the bonding layer and the cap layer can be disposed on opposite surfaces of the conduction layer.

In some embodiments, the bonding layer can comprise tungsten, titanium, chromium, or a tungsten alloy. In some embodiments, the tungsten alloy can comprise about 90 wt % to about 97 wt % tungsten, with the rest of its composition being a matrix of metals. In some embodiments, the matrix of metals can improve the ductility and machinability of the resulting tungsten-based alloy. In some embodiments, the matrix of metals can comprise nickel, iron, copper, chromium, titanium, molybdenum, or cobalt, or combinations thereof. In some embodiments, the tungsten alloy can comprise tungsten carbide. In some embodiments, the tungsten alloy can be 90 wt % tungsten/ 10 wt % titanium.

In some embodiments, the bonding layer can have a thickness from about 0.5 nm to about 1 nm, from about 0.5 nm to about 2 nm, from about 0.5 nm to about 5 nm, from about 0.5 nm to about 10 nm, from about 0.5 nm to about 20 nm, from about 1 nm to about 2 nm, from about 1 nm to about 5 nm, from about 1 nm to about 10 nm, from about 1 nm to about 20 nm, from about 2 nm to about 5 nm, from about 2 nm to about 10 nm, from about 2 nm to about 20 nm, from about 5 nm to about 10 nm, from about 5 nm to about 20 nm, or from about 10 nm to about 20 nm. In some embodiments, the bonding layer can have a thickness of at least about 0.5 nm, at least about 1 nm, at least about 2 nm, at least about 5 nm, at least about 10 nm, or at least about 20 nm. In some embodiments, the bonding layer can have a thickness of at most about 20 nm, at most about 10 nm, at most about 5 nm, at most about 2 nm, at most about 1 nm, or at most about 0.5 nm.

### Cap Layer

In some embodiments, the multi-layer metallic stack may comprise a cap layer (e.g., 104 of FIG. 1) configured to prevent oxide layer formation of the conduction layer and/or improve the solderability of the acoustic device to an electric circuit (e.g., a flexible printed circuit).

In some embodiments, the cap layer can prevent oxide layer formation of the conduction layer. In some embodiments, if the conduction layer comprises aluminum, the cap layer can prevent the formation of aluminum oxide in the conduction layer. In some embodiments, if the conduction layer comprises zinc, the cap layer can prevent the formation of zinc oxide in the conduction layer. In some embodiments, the cap layer can be located further away from the piezoelectric substrate than the bonding layer.

In some embodiments, the cap layer can improve the solderability of the acoustic device to the electric circuit. In some embodiments, the cap layer can have a higher solderability or ease of solderability than the conduction layer. As used herein, solderability defines the ability of a substrate, e.g., metal or metal alloy, to be wetted by a molten electromechanical composition (e.g., a molten solder). In some embodiments, oxidation of a metal or metal alloy can reduce the solderability of the substrate.

In some embodiments, solderability can be quantified or measured by wetting balance analysis, which measures the wetting force between the molten solder and the substrate surface as a function of time. Qualitative test of solderability can be performed by the “dip and look” test, which employs a dipping mechanism, a solder pot, and a low-power microscope. The procedure for using this test for the solderability of wire is defined in American National Standards ANSI/J-STD-002 as well as MIL-STD 202/208F. The dip and look test can be done on bare or plated surfaces. On bare surfaces, the test can indicate surface cleanliness and oxides. On plated surfaces, the test can indicate the solderability of the plated wire when in service.

In some embodiments, solderability can be quantified by measuring the tension force between the acoustic device and the flexible printed circuit that is required to cause the mechanical joint to fail. In some embodiments, solderability can be quantified by measuring the electrical resistance of a solder joint or connection.

In some embodiments, the cap layer can comprise copper, nickel, gold, or tin, or an alloy comprising any combination of the foregoing.

In some embodiments, the cap layer can have a thickness from about 10 nm to about 20 nm, from about 10 nm to about 30 nm, from about 10 nm to about 50 nm, from about 10 nm to about 100 nm, from about 10 nm to about 200 nm, from about 10 nm to about 500 nm, from about 20 nm to about 30 nm, from about 20 nm to about 50 nm, from about 20 nm to about 100 nm, from about 20 nm to about 200 nm, from about 20 nm to about 500 nm, from about 30 nm to about 50 nm, from about 30 nm to about 100 nm, from about 30 nm to about 200 nm, from about 30 nm to about 500 nm, from about 50 nm to about 100 nm, from about 50 nm to about 200 nm, from about 50 nm to about 500 nm, from about 100 nm to about 200 nm, from about 100 nm to about 500 nm, or from about 200 nm to about 500 nm.

In some embodiments, the cap layer can be thicker than the bonding layer. In some embodiments, the cap layer can be at least about 1%, at least about 5%, at least about 10%, at least about 20%, at least about 30%, at least about 40%, at least about 50%, or more, thicker than the bonding layer. In some embodiments, the cap layer can be at most about 50%, at most about 40%, at most about 30%, at most about 20%, at most about 10%, at most about 10%, or less, thicker than the bonding layer. In some embodiments, the cap layer can have a thickness substantially the same as the bonding layer. In some embodiments, the cap layer can be thinner than the bonding layer. In some embodiments, the cap layer can be at least about 1%, at least about 5%, at least about 10%, at least about 20%, at least about 30%, at least about 40%, at least about 50%, or more, thinner than the bonding layer. In some embodiments, the cap layer can be at most about 50%, at most about 40%, at most about 30%, at most about 20%, at most about 10%, at most about 10%, or less, thinner than the bonding layer.

### Substrate

In some embodiments, the piezoelectric substrate (e.g., 101 of FIG. 1) can comprise at least a piezoelectric material. In some embodiments, the piezoelectric material can comprise lithium niobate (LiNbO₃), lithium titanate (Li₂TiO₃), barium titanate (BaTiO₃), lead zirconate titanate (Pb(ZrₓTi₁₋ₓ)O₃ wherein (0≤x≤1)), quartz, zinc oxide, aluminum nitride (AIN), Lanthanum gallium silicate (langasite), lead magnesium niobate-lead titanate (PMN-PT), lead-free potassium sodium niobate (K_{0.5}Na_{0.5}NbO₃ or KNN), a doped derivative of lead-free potassium sodium niobate, polyvinylidene fluoride (PVDF), or a combination thereof. In some embodiments, the piezoelectric substrate can comprise chemically reduced lithium niobate (e.g., black lithium niobate). In some embodiments, the lithium niobate can have a 128° YZ cut orientation.

In some embodiments, the piezoelectric substrate can comprise a 128-degree Y-rotated, X-propagating lithium niobate single crystal. In some embodiments, the substrate can comprise a 41-degree lithium niobate single crystal. In some embodiments, the piezoelectric substrate can comprise zinc oxide. In some embodiments, the zinc oxide can be deposited on a secondary substrate, e.g., silicon or polyamide. In some embodiments, the piezoelectric substrate can comprise aluminum nitride. In some embodiments, the aluminum nitride can be deposited on a secondary substrate, e.g., silicon or polyamide. In some embodiments, the piezoelectric substrate can comprise PMN-PT. In some embodiments, the piezoelectric substrate can comprise a dual substrate. In some embodiments, the piezoelectric substrate can comprise a lithium niobate single crystal grown on a carrier, e.g., sapphire.

In some embodiments, the piezoelectric substrate can have a thickness from about 100 micrometers (μm) to about 200 μm, from about 100 μm to about 250 μm, from about 100 μm to about 300 μm, from about 100 μm to about 400 μm, from about 100 μm to about 500 μm, from about 100 μm to about 600 μm, from about 100 μm to about 700 μm, from about 100 μm to about 800 μm, from about 100 μm to about 900 μm, from about 100 μm to about 1000 μm, from about 200 μm to about 250 μm, from about 200 μm to about 300 μm, from about 200 μm to about 400 μm, from about 200 μm to about 500 μm, from about 200 μm to about 600 μm, from about 200 μm to about 700 μm, from about 200 μm to about 800 μm, from about 200 μm to about 900 μm, from about 200 μm to about 1000 μm, from about 250 μm to about 300 μm, from about 250 μm to about 400 μm, from about 250 μm to about 500 μm, from about 250 μm to about 600 μm, from about 250 μm to about 700 μm, from about 250 μm to about 800 μm, from about 250 μm to about 900 μm, from about 250 μm to about 1000 μm, from about 300 μm to about 400 μm, from about 300 μm to about 500 μm, from about 300 μm to about 600 μm, from about 300 μm to about 700 μm, from about 300 μm to about 800 μm, from about 300 μm to about 900 μm, from about 300 μm to about 1000 μm, from about 400 μm to about 500 μm, from about 400 μm to about 600 μm, from about 400 μm to about 700 μm, from about 400 μm to about 800 μm, from about 400 μm to about 900 μm, from about 400 μm to about 1000 μm, from about 500 μm to about 600 μm, from about 500 μm to about 700 μm, from about 500 μm to about 800 μm, from about 500 μm to about 900 μm, from about 500 μm to about 1000, from about 600 μm to about 700 μm, from about 600 μm to about 800 μm, from about 600 μm to about 900 μm, from about 600 μm to about 1000, from about 700 μm to about 800 μm, from about 700 μm to about 900 μm, from about 700 μm to about 1000 μm, from about 800 μm to about 900 μm, from about 800 μm to about 1000 μm, or from about 900 μm to about 1000 μm.

In some embodiments, the piezoelectric substrate can have a square, rectangular, triangular, or oval shape.

In some embodiments, the piezoelectric substrate can have a dimension from about 3 millimeters (mm) to about 5 mm, from about 3 mm to about 10 mm, from about 3 mm to about 20 mm, from about 3 mm to about 25 mm, from about 3 mm to about 30 mm, from about 3 mm to about 50 mm, from about 5 mm to about 10 mm, from about 5 mm to about 20 mm, from about 5 mm to about 25 mm, from about 5 mm to about 30 mm, from about 5 mm to about 50 mm, from about 10 mm to about 20 mm, from about 10 mm to about 25 mm, from about 10 mm to about 30 mm, from about 10 mm to about 50 mm, from about 20 mm to about 25 mm, from about 20 mm to about 30 mm, from about 20 mm to about 50 mm, from about 25 mm to about 30 mm, from about 25 mm to about 50 mm, or from about 30 mm to about 50 mm.

### Process Methods

In some embodiments, the present disclosure provides a method of forming an acoustic device. In some embodiments, the method comprises providing a piezoelectric substrate; and forming a multi-layer metallic stack on the piezoelectric substrate. In some embodiments, the multi-layer metallic stack can be formed via a single vacuum process. In some embodiments, forming the multi-layer metallic stack can comprise sequentially depositing a bonding layer, a conduction layer, and a cap layer within a single vacuum process. In some embodiments, the forming of the multi-layer metallic stack can comprise sequentially depositing a bonding layer, a conduction layer, a barrier layer, and a cap layer within a single vacuum process. In some embodiments, the multi-layer metallic stack can be formed via a plurality of vacuum processes. In some embodiments, the vacuum process may prevent the formation of an oxide on any of the layers.

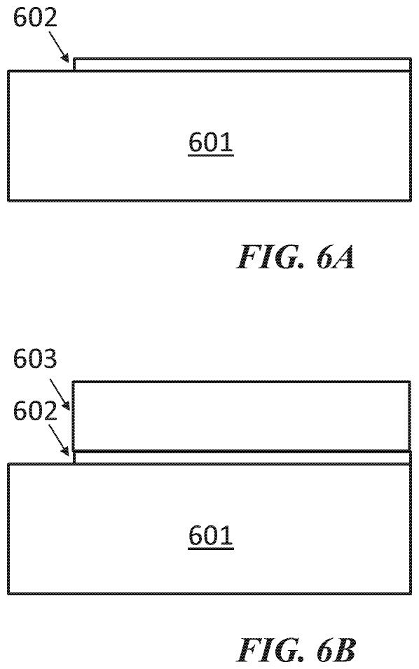

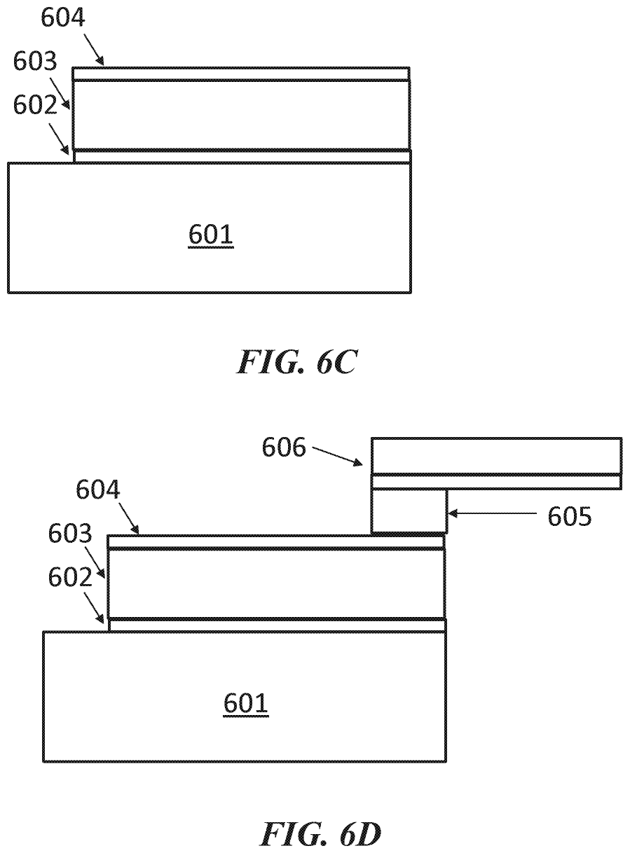

FIGS. 6A-6C show cross-sectional views of an exemplary acoustic device during the fabrication process. FIG. 6A shows a bonding layer 602 has been deposited on a substrate 601. FIG. 6B shows a conduction layer 603 has been deposited on the bonding layer 602. FIG. 6C shows a cap layer 604 has been deposited on the conduction layer 603.

FIG. 6D shows a cross-sectional view of an exemplary acoustic device that has been soldered to a printed circuit, whereby the cap layer 604 and the printed circuit 606 have been soldered via an electromechanical layer 605 (e.g., a solder paste).

In some embodiments, the single vacuum process can comprise sputter deposition or electron beam deposition.

In some embodiments, the multi-layer metallic stack can be formed via a plurality of vacuum processes comprising one or more plasma etch or laser ablation cleaning steps prior to a series of deposition steps. In some embodiments, the series of deposition steps may be performed using pulsed laser deposition, electron beam deposition, or sputtering.

In some embodiments, the bonding layer, the conduction layer, and the cap layer can be sequentially deposited using a sputtering process. In some embodiments, the bonding layer, the conduction layer, the barrier layer, and the cap layer can be sequentially deposited using a sputtering process.

In some embodiments, the present disclosure provides a method of forming an acoustic module, comprising: applying a solder to an electrical circuit; aligning and placing the acoustic device disclosed herein onto the electrical circuit; and using a thermal reflow process to form one or more solder interconnects that electromechanically couple the acoustic device to the electrical circuit.

In some embodiments, the solder can be applied to the electrical circuit using a stencil. In some embodiments, the thermal reflow process may comprise heating the solder to melt the solder. In some embodiments, the thermal reflow process may further comprise cooling the solder to solidify the solder joints.

In some embodiments, the present disclosure provides a method of forming an acoustic module. The method comprises (i) depositing a titanium bonding layer on a substrate, (ii) depositing an aluminum conduction layer on the bonding layer, and (iii) depositing a copper cap layer. In some embodiments, the depositing in (i), (ii), and (iii) can be performed with sputter deposition. In some embodiments, the titanium bonding layer may be from about 2 nm to about 5 nm in thickness. In some embodiments, the aluminum conduction layer may be from about 0.5 μm to about 2 μm in thickness. In some embodiments, the copper cap layer may be from about 60 nm to about 200 nm in thickness.

In some embodiments, the substrate can comprise lithium niobate, which is single crystalline and has a large piezoelectric coupling factor. In some embodiments, lithium niobate may crack when subjected to rapid heat changes due to its pyroelectric property. In some embodiments, the soldering process rapidly transfers heat to the substrate, which may damage the lithium niobate substrate. In some embodiments, soldering in a reflow oven allows for gradual heating while still forming optimal solder joints. Therefore, when lithium niobate is used as a substrate, soldering in a reflow oven can minimize or eliminate the damage to the substrate.

In some embodiments, the substrate can comprise chemically reduced lithium niobate or black lithium niobate. Black lithium niobate has higher electrical conductivity and high near UV absorption. Black lithium niobate has reduced pyroelectric effects/charges and therefore improves the manufacturability of the acoustic devices during photolithography and soldering. In some embodiments, black lithium niobate can reduce the static discharge time by at least about 10%, at least about 20%, at least about 30%, at least about 40%, at least about 50%, at least about 60%, at least about 70%, at least about 80%, at least about 90%, or more, when compared with lithium niobate.

In some embodiments, the black lithium niobate can be coated with titanium, aluminum, and/or copper.

In some embodiments, the method further comprises applying lead-free solder paste (e.g., solder paste SAC 305) to a flexible printed circuit (FPC), which consists of copper traces printed on polyamide. In some embodiments, the method further comprises soldering the acoustic device to the FPC. In some embodiments, the acoustic device can be placed by hand. In some embodiments, the acoustic device can be placed by a place machine. In some embodiments, the acoustic device can be placed with a pick-and-place machine.

### Acoustic Device

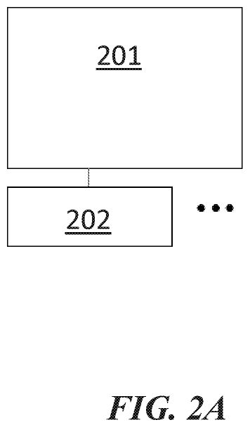

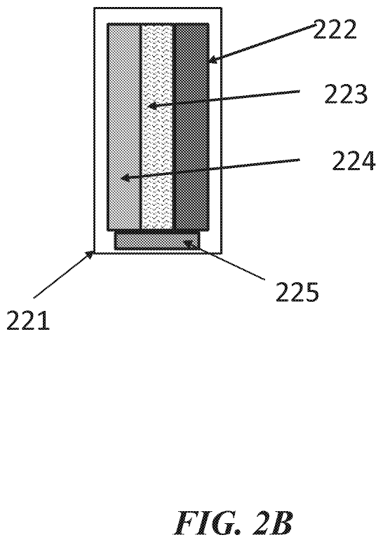

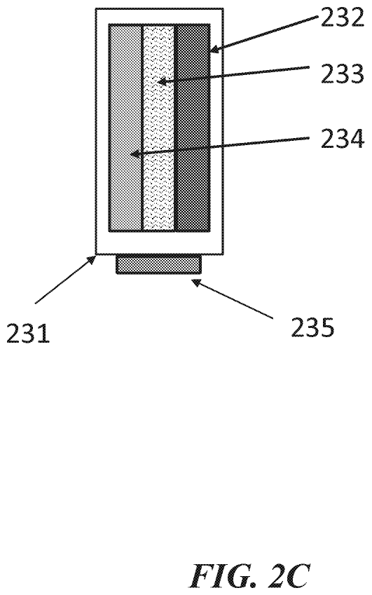

In some embodiments, the acoustic device may be coupled to an electrochemical cell having any form factor. FIG. 2A shows an acoustic device 202 operably coupled to a device 201 comprising one or more electrochemical cells. In some embodiments, the electrochemical cell can have a form factor of cylindrical, prismatic, or pouch. In some embodiments, the electrochemical cell may be configured to adapt to the shape, contours, and/or surface features of its surroundings. The orientation, location, number, and/or operation frequency of the acoustic device may be adjusted accordingly relative to the electrochemical cell in order to effectively agitate electrolyte over the electrochemical cell and/or electrodes, regardless of the form factor of the electrochemical cell. The acoustic device may be integrated into various types of electrochemical cells in a variety of different manners. For example, for a pouch cell, the acoustic device may be attached to any surface of the pouch cell. For a cylindrical cell, the acoustic device may be positioned from the bottom and/or top flat surfaces, or along the edges of the cylinder rolls. For a coin cell, the acoustic device may be positioned onto the flat surfaces or the edge of the round shape of the coin cell. In some embodiments, the acoustic device can be assembled, mounted, or integrated adjacent to the electrochemical device in a number of configurations. In some embodiments, the acoustic device can be mounted relative to the center (e.g., centered or offset from the center) of the electrochemical device. In some embodiments, the acoustic device can be mounted adjacent to an edge of the electrochemical device, such that the acoustic device is offset from the center of the electrochemical device.

In some embodiments, the acoustic device can be coupled to an interior or internal surface of the electrochemical cell. In some embodiments, the acoustic device can be disposed at various locations within the interior of the electrochemical cell.

In some embodiments, the acoustic device can be positioned relative to an electrode gap or direction of cation flow within the electrochemical device. For example, the acoustic device can be placed with respect to a central axis or plane of the electrochemical device. The axes or planes can correspond to a direction of flow of the mobile species (e.g., cations or ions) of the electrochemical device. The acoustic waves can be streamed in a direction substantially parallel, antiparallel, orthogonal, or a combination thereof, to the electrode gap or the direction of flow of the mobile species.

In some embodiments, multiple acoustic devices can be integrated into an acoustic module. In some embodiments, multiple acoustic devices can be coupled to (e.g., mounted to) an electrochemical device. In some embodiments, each of the multiple acoustic devices can be mounted onto an external surface of the electrochemical device. In some embodiments, each of the multiple acoustic devices may be mounted onto one external surface of the electrochemical device. In some embodiments, the multiple acoustic devices can be mounted onto the external surface such that the multiple acoustic devices can interface with at least two external surfaces of the electrochemical device. In some embodiments, at least two external surfaces can be parallel to each other. In some embodiments, at least two external surfaces can be opposite to one another. In some embodiments, at least two external surfaces can be orthogonal to one another.

In some embodiments, a plurality of acoustic devices can be used to generate acoustic waves in a plurality of directions (e.g., parallel and/or orthogonal to the direction of Li⁺ migration).

In some embodiments, one or more coupling agents can be used to secure the acoustic device to the electrochemical device. In some embodiments, the coupling agent can establish a connection between the housing of the acoustic device and the electrochemical device. In some embodiments, the coupling agent can be a chemical agent. In some embodiments, the coupling agent can comprise a liquid, a gel, or a paste. In some embodiments, the coupling agent can be moderately viscous and nontoxic. In some embodiments, the coupling agent can comprise silicone grease. In some embodiments, the acoustic wave may be coupled through an ultrasound gel into the electrochemical device, generating acoustic streaming inside the electrochemical device. In some embodiments, the coupling agent can be a physical mechanism, e.g., magnetic coupling or mechanical coupling, e.g., by compression. In some embodiments, the coupling agent can partially or entirely fill a gap between the electrochemical device and the acoustic device. In some embodiments, the coupling agent can be aligned with the acoustic device. In some embodiments, the coupling agent may not be aligned to the acoustic device.

In some embodiments, each of the electrochemical device, acoustic device, and coupling agent (when present) can comprise a plurality of dimensions, such as a length, a width (e.g., a thickness), and a height. In some embodiments, each of the dimensions of the electrochemical device, acoustic device, and coupling agent (when present) can be the same.

FIG. 2B shows a configuration of an electrochemical cell and an acoustic device coupled to the interior of the electrochemical cell. The electrochemical cell comprises a cathode 222, an electrolyte 223, and an anode 224. The electrochemical cell is encased in an enclosure 221. The acoustic device 225 is also encased in the enclosure 221.

In some embodiments, the acoustic device can be coupled to or mounted to an exterior or external surface of the electrochemical cell. In some embodiments, the external surface can be planar or non-planar. In some embodiments, the electrochemical device can be a cylindrical device, and the acoustic device can be mounted over the rounded surface. In some embodiments, the external surface can be the largest surface of the electrochemical device. In some cases, the external surface can be the smallest surface of the electrochemical device.

In some embodiments, the acoustic device disposed at, mounted to, or coupled to an external surface of the electrochemical cell has more flexibility in the design of the acoustic device in terms of the size, shape, contours, and/or surface features.

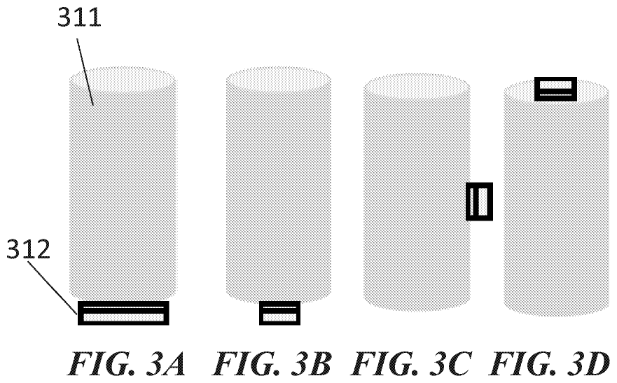

FIG. 2C shows a configuration of an electrochemical cell and an acoustic device coupled to the exterior of the electrochemical cell. The electrochemical cell comprises a cathode 232, an electrolyte 233, and an anode 234. The electrochemical cell is encased in an enclosure 231. The acoustic device 235 is disposed outside of the enclosure 231. In some embodiments, the acoustic device can be disposed at various locations on the exterior surface of a device. FIGS. 3A-3D show exemplary configurations of acoustic device 312 coupled to an electrochemical cell 311 where the acoustic device is at different locations at the external surface of the electrochemical cell, e.g., a cylindrical electrochemical cell. In some embodiments, the acoustic device may be positioned relative to the electrochemical cell to direct acoustic waves to a specific region within the electrochemical cell.

In some embodiments, a plurality of electrochemical cells can be encased in a common enclosure to form an electrochemical device.

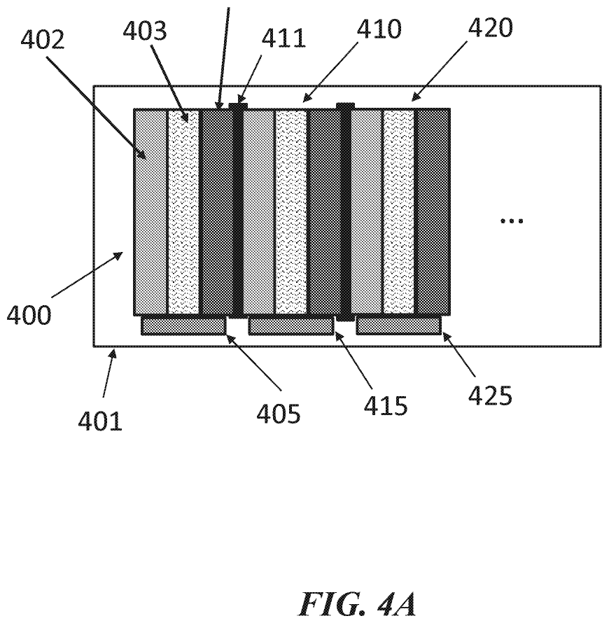

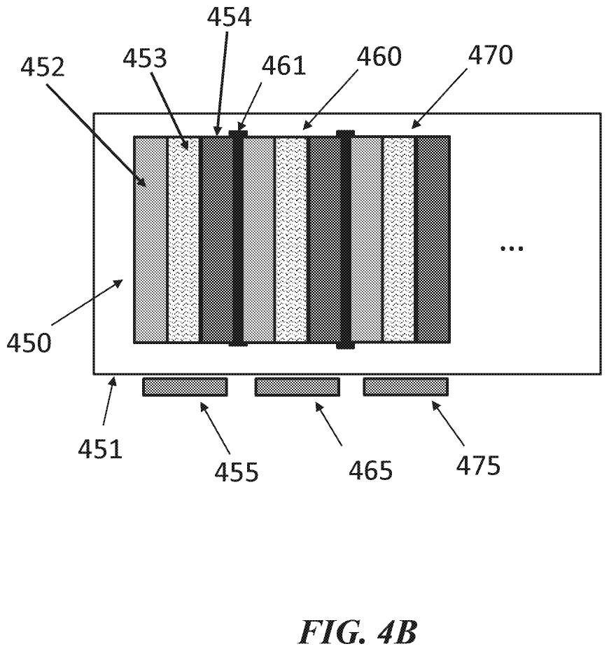

In some embodiments, a plurality of acoustic devices can be coupled to the interior of the electrochemical device. FIG. 4A shows an example of a plurality of acoustic devices coupled to an interior of an electrochemical device comprising a plurality of electrochemical cells. The electrochemical device comprises a common enclosure 401 encasing a plurality of electrochemical cells, e.g., 400, 410, and 420, and a plurality of acoustic devices, e.g., 405, 415, and 425. The neighboring electrochemical cells are separated by a bipolar plate, e.g., 411. An electrochemical cell 400 comprises an anode 402, an electrolyte 403, and a cathode 404. An electrochemical cell of a plurality of electrochemical cells can be coupled to an acoustic device. For example, electrochemical cell 400 is coupled to acoustic device 405, and electrochemical cell 410 is coupled to acoustic device 415.

In some embodiments, a plurality of acoustic devices can be coupled to the exterior of the electrochemical device. FIG. 4B shows an example of a plurality of acoustic devices coupled to the exterior of an electrochemical device comprising a plurality of electrochemical cells. The electrochemical device comprises a common enclosure 451 encasing a plurality of electrochemical cells, e.g., 450, 460, and 470, and a plurality of acoustic devices, e.g., 455, 465, and 475. The neighboring electrochemical cells are separated by a bipolar plate, e.g., 461. An electrochemical cell 450 comprises an anode 452, an electrolyte 453, and a cathode 454. An electrochemical cell of a plurality of electrochemical cells can be coupled to an acoustic device. For example, electrochemical cell 450 is coupled to acoustic device 455, and electrochemical cell 460 is coupled to acoustic device 465.

### Acoustic Module

In some embodiments, the present disclosure provides an acoustic module comprising: an acoustic device and an electrical circuit disclosed in the present disclosure; and one or more solder interconnects (or joints) configured to electromechanically couple the acoustic device to the electrical circuit.

In some embodiments, the electrical circuit can comprise a flexible printed circuit (FPC). In some embodiments, the flexible printed circuit can comprise a metallic layer of traces, e.g., copper traces, printed on a substrate. In some embodiments, the substrate can comprise polyamide. In some embodiments, the electrical circuit can comprise a printed circuit board.

In some embodiments, the one or more solder interconnects can comprise a lead-free solder. In some embodiments, the lead-free solder can comprise a metal selected from the group consisting of tin, copper, silver, nickel, zinc, bismuth, antimony, and combinations thereof. Non-limiting examples of lead-free solder comprise 96.5% Sn/3% Ag/0.5% Cu (SAC305), 95.5% Sn/3.8% Ag/0.7% Cu, 95.5Sn 4.0Ag0.5Cu, 93.5% Sn/3% Sb/2% Bi/1.5% Cu, 99.3Sn 0.7Cu0.06Ni0.005Ge(SN100C), 95.5% Sn/3.5% Ag/1% Zn, 96.5% Sn/3.5% Ag, 95% Sn/5% Ag, 96% Sn/4% Ag, 97.5% Sn/2.5% Ag, 97% Sn/2% Cu/0.8% Sb/0.2% Ag, 99.3% Sn/0.7% Cu, 97% Sn/3% Cu, 95% Sn/5% Sb, 91.5% Sn/8.5% Sb, 65% Sn/25% Ag/10% Sb, 42% Sn/58% Bi, 91% Sn/9% Zn, and 11%Ag/89 % Bi. In some embodiments, the lead-free solder can comprise SAC 305. In some embodiments, the lead-free solder can have a melting temperature from about 130° C. to about 400° C. In some embodiments, the lead-free solder can have a melting temperature from about 200° C. to about 250° C.

In some embodiments, the lead-free solder can be initially applied to the electrical circuit. In some embodiments, the lead-free solder can be initially applied to the electrical circuit using a stencil. The stencil thickness partially determines the vertical distance between the acoustic device and the flat bottom of the electrochemical device or cell, which is a critical dimension because it determines the amount of acoustic energy that is transferred into the electrochemical device or cell. In some embodiments, the stencil can have a thickness from about 25 μn to about 75 μm.

In some embodiments, the one or more solder interconnects can be formed using a reflow process to thereby electromechanically couple the acoustic device to the electrical circuit.

In some embodiments, a height of the one or more solder interconnects can be from about 10 μm to about 20 μm, from about 10 μm to about 25 μm, from about 10 μm to about 50 μm, from about 10 μm to about 75 μm, from about 10 μm to about 100 μm, from about 20 μm to about 25 μm, from about 20 μm to about 50 μm, from about 20 μm to about 75 μm, from about 20 μm to about 100 μm, from about 25 μm to about 50 μm, from about 25 μm to about 75 μm, from about 25 μm to about 100 μm, from about 50 μm to about 75 μm, from about 50 μm to about 100 μm, or from about 75 μm to about 100 μm.

In some embodiments, the one or more solder interconnects can comprise a plurality of solder interconnects having a substantially uniform height or thickness. Repeatable, low-resistance, and/or high mechanical-strength solder interconnects (or joints) are critical because the signal that passes through this interconnect to the acoustic device determines the acoustic wave it produces. If the impedance of the joint is significantly different from one joint to the next in an array of acoustic devices, the performance of the entire electrochemical device may be reduced. In some cases, if the joints are initially identical but change significantly due to mechanical stress, the performance of the entire electrochemical device may be reduced.

In some embodiments, the acoustic module can comprise a transducer disclosed herein.

### Acoustic Waves

The acoustic device, disclosed herein, can emit tunable acoustic waves (e.g., specifically tuned acoustic waves) which can create microscale or nanoscale acoustofluidics in a mobile species of the electrochemical cell (e.g., micro-stirring effect). The acoustic waves can have a direct influence on the performance of electrochemical cells. The micro-stirring effect by the acoustic waves can enhance the mobility and movement of the mobile species. In some embodiments, the acoustic waves can lead to an even distribution of the mobile species, optimize the concentration gradient, and/or improve electrode surface potential. In some embodiments, the acoustic waves can enhance electrochemical reaction kinetics, ensuring that the reactions occur at the most optimal rate. The acoustic device can be tuned to emit acoustic waves of specific frequencies, amplitudes, and durations, making it adaptable to different electrochemical cell types and sizes.

In some embodiments, the acoustic waves generated by the acoustic device can reduce the bulk impedance of the electrochemical cell by promoting mobility, availability, and/or uniformity in distribution of mobile species within the electrochemical cell. In some embodiments, the bulk impedance of the electrochemical cell can be reduced by at least about 1%, at least about 2%, at least about 5%, at least about 10%, at least about 15%, at least about 20%, at least about 30%, at least about 40%, at least about 50%, at least about 60%, at least about 70%, at least about 80%, or more compared to another electrochemical cell that is operated without the acoustic waves.

In some embodiments, the acoustic waves can facilitate or increase mass transport of the mobile species within the electrochemical cell. In some embodiments, the mass transport rate of mobile species in the electrochemical cell can be increased by at least about 1%, at least about 2%, at least about 5%, at least about 10%, at least about 15%, at least about 20%, at least about 30%, at least about 40%, at least about 50%, at least about 60%, at least about 70%, at least about 80%, at least about 90%, at least about 100%, or more compared to another electrochemical cell that is operated without the acoustic waves.

In some embodiments, the acoustic waves can enhance the kinetic rate of reactions within the electrochemical cell. In some embodiments, the kinetic rate of reactions within the electrochemical cell can be increased by at least about 1%, at least about 2%, at least about 5%, at least about 10%, at least about 15%, at least about 20%, at least about 30%, at least about 40%, at least about 50%, at least about 60%, at least about 70%, at least about 80%, at least about 90%, at least about 100%, or more compared to another electrochemical cell that is operated without the acoustic waves.

In some embodiments, the acoustic waves generated by the acoustic device can comprise at least one of the following: surface acoustic waves (SAW), Lamb waves, love waves, flexural waves, thickness mode vibrations, mixed-mode waves, longitudinal waves, shear mode vibrations, bulk wave vibrations, or any combination(s) thereof.

In some embodiments, the acoustic waves generated by the acoustic device may propagate through an electrolyte filling the interior of the electrochemical cell. In some embodiments, the acoustic waves may agitate the electrolyte, thereby homogenizing the distribution of mobile species, e.g., cations or anions, in the electrolyte during the charging of the electrochemical cell. Homogenizing the distribution of the mobile species in the electrolyte may decrease the concentration gradient of the mobile species in the electrolyte, such that the mobile species are distributed more evenly throughout the electrolyte. The homogenization of the distribution of the mobile species may increase the uniformity of the deposits of the mobile species on at least one of the electrodes.

In some embodiments, the acoustic waves can be customized or tuned based at least in part on a type, capacity, function, shape, size, form factor, and/or operating conditions of the electrochemical cell.

In some embodiments, the acoustic waves have a frequency ranging from 10 hertz (Hz) to 500 megahertz (MHz). In some embodiments, the frequency of the acoustic waves can range from about 10 Hz to about 100 Hz, from about 10 Hz to about 1 kilohertz (kHz), from about 10 Hz to about 10 kHz, from about 10 Hz to about 100 kHz, from about 10 Hz to about 1 MHz, from about 10 Hz to about 100 MHz, from about 10 Hz to about 500 MHz, from about 100 Hz to about 1 kHz, from about 100 Hz to about 10 kHz, from about 100 Hz to about 100 kHz, from about 100 Hz to about 1 MHz, from about 100 Hz to about 100 MHz, from about 100 Hz to about 500 MHz, from about 1 kHz to about 10 kHz, from about 1 kHz to about 100 kHz, from about 1 kHz to about 1 MHz, from about 1 kHz to about 100 MHz, from about 1 kHz to about 500 MHz, from about 10 kHz to about 100 kHz, from about 10 kHz to about 1 MHz, from about 10 kHz to about 100 MHz, from about 10 kHz to about 500 MHz, from about 100 kHz to about 1 MHz, from about 100 kHz to about 100 MHz, from about 100 kHz to about 500 MHz, from about 1 MHz to about 100 MHz, from about 1 MHz to about 500 MHz, or from about 100 MHz to about 500 MHz.

In some embodiments, the acoustic waves have a power ranging from 0.1 milliwatts (mW) to 500 megawatts (MW). In some embodiments, the power of the generated acoustic waves can range from about 0.1 mW to about 1 mW, from about 0.1 mW to about 1 W, from about 0.1 mW to about 10 W, from about 0.1 mW to about 100 W, from about 0.1 mW to about 1 kilowatt (kW), from about 0.1 mW to about 10 kW, from about 0.1 mW to about 100 kW, from about 0.1 mW to about 1 MW, from about 1 mW to about 1 W, from about 1 mW to about 10 W, from about 1 mW to about 100 W, from about 1 mW to about 1 kW, from about 1 mW to about 10 kW, from about 1 mW to about 100 kW, from about 1 mW to about 1 MW, from about 1 W to about 10 W, from about 1 W to about 100 W, from about 1 W to about 1 kW, from about 1 W to about 10 kW, from about 1 W to about 100 kW, from about 1 W to about 1 MW, from about 10 W to about 100 W, from about 10 W to about 1 kW, from about 10 W to about 10 kW, from about 10 W to about 100 kW, from about 10 W to about 1 MW, from about 100 W to about 1 kW, from about 100 W to about 10 kW, from about 100 W to about 100 kW, from about 100 W to about 1 MW, from about 1 kW to about 10 kW, from about 1 kW to about 100 kW, from about 1 kW to about 1 MW, from about 10 kW to about 100 kW, from about 10 kW to about 1 MW, or from about 100 kW to about 1 MW.

In some embodiments, the power of the generated acoustic waves can prevent the formation of metal deposits (e.g., Li deposits) without structurally perturbing the components within the electrochemical cell.

In some embodiments, the acoustic waves have one or more waveforms selected from the group consisting of a continuous sine wave, a square wave, and a triangular wave.

In some embodiments, the acoustic waves are generated with on/off pulsing ranging from 0% to 100%. In some embodiments, the acoustic waves are generated with on/off pulsing ranging from about 0% to about 10%, from about 0% to about 20%, from about 0% to about 30%, from about 0% to about 40%, from about 0% to about 50%, from about 0% to about 60%, from about 0% to about 70%, from about 0% to about 80%, from about 0% to about 90%, from about 0% to about 100%, from about 10% to about 20%, from about 10% to about 30%, from about 10% to about 40%, from about 10% to about 50%, from about 10% to about 60%, from about 10% to about 70%, from about 10% to about 80%, from about 10% to about 90%, from about 10% to about 100%, from about 20% to about 30%, from about 20% to about 40%, from about 20% to about 50%, from about 20% to about 60%, from about 20% to about 70%, from about 20% to about 80%, from about 20% to about 90%, from about 20% to about 100%, from about 30% to about 40%, from about 30% to about 50%, from about 30% to about 60%, from about 30% to about 70%, from about 30% to about 80%, from about 30% to about 90%, from about 30% to about 100%, from about 40% to about 50%, from about 40% to about 60%, from about 40% to about 70%, from about 40% to about 80%, from about 40% to about 90%, from about 40% to about 100%, from about 50% to about 60%, from about 50% to about 70%, from about 50% to about 80%, from about 50% to about 90%, from about 50% to about 100%, from about 60% to about 70%, from about 60% to about 80%, from about 60% to about 90%, from about 60% to about 100%, from about 70% to about 80%, from about 70% to about 90%, from about 70% to about 100%, from about 80% to about 90%, from about 80% to about 100%, or from about 90% to about 100%.

In some embodiments, the acoustic waves are generated with a timescale period ranging from about 1 microsecond (μs) to about 1 millisecond (ms). In some embodiments, the timescale period can range from about 1 μs to about 10 μs, from about 1 μs to about 50 μs, from about 1 μs to about 100 μs, from about 1 μs to about 250 μs, from about 1 μs to about 500 μs, from about 1 μs to about 750 μs, from about 1 μs to about 1 ms, from about 10 μs to about 50 μs, from about 10 μs to about 100 μs, from about 10 μs to about 250 μs, from about 10 μs to about 500 μs, from about 10 μs to about 750 μs, from about 10 μs to about 1 ms, from about 50 μs to about 100 μs, from about 50 μs to about 250 μs, from about 50 μs to about 500 μs, from about 50 μs to about 750 μs, from about 50 μs to about 1 ms, from about 100 μs to about 250 μs, from about 100 μs to about 500 μs, from about 100 μs to about 750 μs, from about 100 μs to about 1 ms, from about 250 μs to about 500 μs, from about 250 μs to about 750 μs, from about 250 μs to about 1 ms, from about 500 μs to about 750 μs, from about 500 μs to about 1 ms, or from about 750 μs to about 1 ms. In some embodiments, the timescale period can be about 1 μs, about 10 μs, about 50 μs, about 100 μs, about 250 μs, about 500 μs, about 750 μs, or about 1 ms.

### Electrochemical Cell

In some embodiments, the electrochemical cell can be used in a solid-state or semi-solid-state battery, a fuel cell, an electrolyzer, a capacitor, a supercapacitor, a flow battery, or a metal-air battery. In some embodiments, the electrochemical cell can be regularly shaped or irregularly shaped. In some embodiments, the electrochemical device can comprise at least one, at least two, at least three, at least four, at least five, at least six, at least seven, at least eight, at least nine, at least ten, at least 20, at least 30, at least 40, at least 50, at least 60, at least 70, at least 80, at least 90, at least 100, or more electrochemical cells. In some embodiments, the electrochemical cells can comprise cylindrical, prismatic, or pouch cells.

In some embodiments, the electrochemical cell can be any type of battery, including, for example, a lithium (Li) battery, a sodium (Na) battery, a potassium (K) battery, a copper (Cu) battery, a zinc (Zn) battery, a magnesium (Mg) battery, or a lithium ion battery.

In some embodiments, the electrochemical cell can comprise at least two electrodes. In some embodiments, the electrochemical cell can comprise an anode and a cathode. In some embodiments, the anode and the cathode can be separated by an ionically conductive bridge.

In some embodiments, the cathode can comprise Li. In some embodiments, the cathode can comprise a material selected from the group consisting of LiFePO₄; LiFeₓMn_{y}PO₄, wherein x+y=1; LiMn₂O₄; LiNi_{0.5}Mn_{1.5}O₄; LiNiₓCo_{y}Mn_{z}O₂, wherein x+y+z=1; LiCoO₂; LiNiₓCo_{y}Al_{z}O₂, wherein x+y+z=1; and aLiNiₓCo_{y}Mn_{z}O₂·(1-a)Li₂MnO₃, wherein a is from 0 to 1 and x+y+z=1. In some embodiments, the cathode is Li-free. In some embodiments, the cathode can comprise a material selected from the group of oxides, fluorides, oxyfluorides, sulfur-based materials, and gases. In some embodiments, the cathode can be lithium-containing intercalation chemistry-based or intercalation-type layered (e.g., involving transition metal oxides, transition metal phosphate, vanadium oxides, molybdenum oxides) for Li ion battery or Li metal battery. In some embodiments, the cathode can be sodium-containing intercalation chemistry-based or intercalation-type layered (e.g., involving transition metal oxides, transition metal phosphate, iron hexacyanoferrate (prussian blue, prussian white), vanadium oxides, molybdenum oxides) for Na ion battery or Na metal battery. In some embodiments, the cathode can be potassium-containing intercalation chemistry-based or intercalation type-layered (e.g., involving transition metal oxides, transition metal phosphate, iron hexacyanoferrate (prussian blue, prussian white), vanadium oxides, molybdenum oxides) for K ion battery or K metal battery. In some embodiments, the cathode can comprise a layered lithium intercalated transition metal oxides, lithium intercalated transition metal oxides, lithium intercalated phosphate, pre-lithiated sulfur, pre-lithiated multivalent metal fluorides, pre-lithiated multivalent metal sulfides, or pre-lithiated multivalent metal oxides. In some embodiments, the cathode can comprise a layered sodium intercalated transition metal oxide, sodium intercalated transition metal oxide, sodium intercalated phosphate, sodium intercalated iron hexacyanoferrate (prussian blue, prussian white), pre-sodiated sulfur, pre-sodiated multivalent metal fluorides, pre-sodiated multivalent metal sulfides, or pre-sodiated multivalent metal oxides. In some embodiments, the cathode can comprise a layered potassium intercalated transition metal oxide, potassium intercalated transition metal oxide, potassium intercalated phosphate, potassium intercalated iron hexacyanoferrate (prussian blue, prussian white), pre-potassiated sulfur, pre-potassiated multivalent metal fluorides, pre-potassiated multivalent metal sulfides, or pre-potassiated multivalent metal oxides.

In some embodiments, the anode can be a Li-containing material. In some embodiments, the Li-containing material can be Li metal foil, Li metal on Cu foil, Li metal on carbon substrate, Li metal on porous metal substrate, or Li metal on porous carbon substrate. In some embodiments, the anode comprises an anode material, for example, graphite, graphene, Al, Cu, Si, Sn, SiOₓ, SnOₓ, P, lithium titanium oxide (LTO), hard carbon, or soft carbon, or a combination thereof. In some embodiments, the electrochemical cell can comprise an electrolyte. In some embodiments, the electrolyte can be a nonaqueous electrolyte, an aqueous electrolyte (e.g., a water in salt electrolyte), a semi-solid electrolyte, a liquified gas electrolyte, or a polymer or polymer gel electrolyte. The electrolyte material can be a porous material, such that cations or charge carriers can diffuse through the electrolyte. For example, the electrolyte material can be a porous material with an average pore diameter suitable for Li ion diffusion. In some embodiments, the electrolyte salt can be LiPF₆. In some cases, the electrolyte material can be an aqueous electrolyte, such as an ionic liquid. The ionic liquid can be a quaternary amine, such as imidazolium, NH₄ ⁺, pyrrolidinium, or piperidinium. In some embodiments, a nonaqueous electrolyte may be present. In some embodiments, the nonaqueous electrolyte may comprise a carbonate, an ether, a phosphate, a sulfone, an ionic liquid, an amide, a ketone, an ester, an alcohol, or an aromatic, or combinations thereof. In some embodiments, the carbonate may comprise ethylene carbonate (EC), propylene carbonate (PC), or dimethyl carbonate (DMC), or combinations thereof. In some embodiments, the ether may comprise diethyl ether (DEE), tetrahydrofuran (THF), or dioxolane (DIOX), or combinations thereof. In some embodiments, the phosphate may comprise trimethyl phosphate (TMP), triethyl phosphate (TEP), or combinations thereof. In some embodiments, the sulfone may comprise sulfolane, 1,3-propane sulfone, or combinations thereof. In some embodiments, the ionic liquid may comprise an imidazolium-based salt, a pyridinium-based salt, or combinations thereof. In some embodiments, the amide may comprise N, N-dimethylformamide (DMF), N-methylacetamide (NMA), or combinations thereof. In some embodiments, the ketone may be acetone or 2,3-butanedione. In some embodiments, the ester may be ethyl acetate or butyl acetate. In some embodiments, the alcohol may comprise methanol, ethanol, propanol, isopropanol, or butanol, or combinations thereof. In some embodiments, the nonaqueous electrolyte may comprise an aromatic solvent, such as toluene, xylene, or combinations thereof.

In some embodiments, the electrochemical cell having the integrated acoustic device may be coupled with a controller configured to: determine, based at least on a feedback signal, a morphology of an interior of the electrochemical cell; and control, based at least on the morphology, an operation of the electrochemical cell. In some embodiments, the controller may be configured to terminate the operation of the electrochemical cell in response to the feedback signal indicating an adverse morphology, including, for example, the presence of dendrites and/or air bubbles on the surface of the electrodes. In some embodiments, the controller may terminate the operation of the electrochemical cell by at least electrically decoupling the electrochemical cell from an electric load of the electrochemical cell and/or another electrochemical cell in the same electrochemical cell array, upon detecting the presence of adverse morphology.

### Transducer

In some embodiments, the acoustic device comprises a transducer configured to isolate the acoustic waves to a surface of the electrochemical cell, increase maximum vibrational amplitude for a given voltage signal, and/or generate a large vibrational amplitude at a relatively low frequency. In some embodiments, the transducer is configured to occupy minimal lateral space on the electrochemical device. In some embodiments, the transducer comprises a conductive material. In some embodiments, the transducer comprises a metal selected from the group consisting of titanium, aluminum, copper, chromium, gold, nickel, and/or tin. In some embodiments, the transducer is patterned onto a substrate to form an acoustic device for various applications. In some embodiments, the transducer is selected from the group consisting of an interdigital transducer, a thickness mode transducer, and a lamb wave transducer. In some embodiments, the interdigital transducer comprises a straight finger interdigital transducer (SIDT) or a focused interdigital transducer (FIDT). In some embodiments, the transducer can be deposited on the substrate.

### Computer Systems

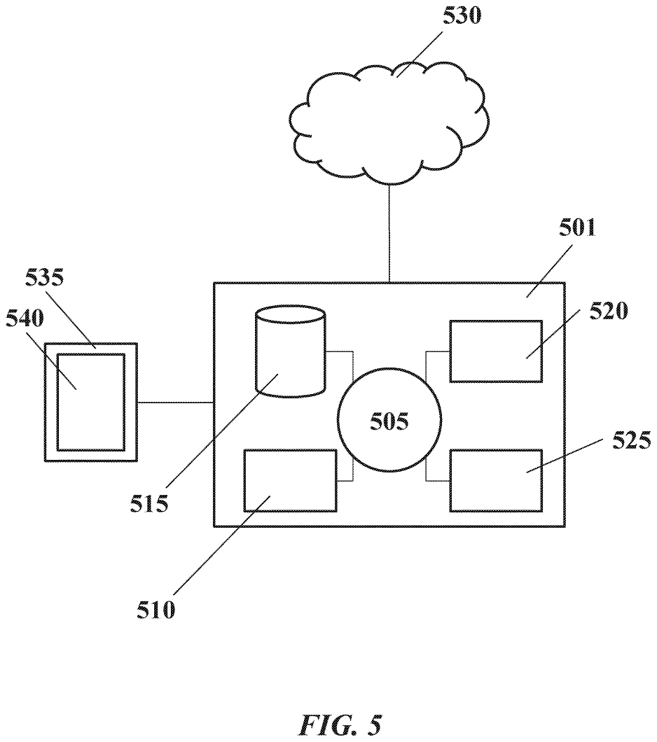

The present disclosure provides computer systems that are programmed to implement methods of the disclosure. FIG. 5 shows a computer system 501 that is programmed or otherwise configured to control an output from a device, system, or apparatus according to the embodiments disclosed herein. For example, the computer system 501 may be configured to control an output from an acoustic device or an electrochemical cell as described herein. The computer system 501 can regulate various aspects of generating acoustic waves of the present disclosure, such as, for example, frequency, wavelength, amplitude, or power, types of waveforms. The computer system 501 can be an electronic device of a user or a computer system that is remotely located with respect to the acoustic device or acoustic module according to the disclosure. The electronic device can be a mobile electronic device.

The computer system 501 includes a central processing unit (CPU, also “processor” and “computer processor” herein) 505, which can be a single core or multi-core processor, or a plurality of processors for parallel processing. The computer system 501 also includes memory or memory location 510 (e.g., random-access memory, read-only memory, flash memory), electronic storage unit 515 (e.g., hard disk), communication interface 520 (e.g., network adapter) for communicating with one or more other systems, and peripheral devices 525, such as cache, other memory, data storage, and/or electronic display adapters. The memory 510, storage unit 515, interface 520, and peripheral devices 525 are in communication with the CPU 505 through a communication bus (solid lines), such as a motherboard. The storage unit 515 can be a data storage unit (or data repository) for storing data. The computer system 501 can be operatively coupled to a computer network (“network”) 530 with the aid of the communication interface 520. The network 530 can be the Internet, an intranet and/or extranet, or an intranet and/or extranet that is in communication with the Internet. The network 530, in some cases, is a telecommunication and/or data network.

The network 530 can include one or more computer servers, which can enable distributed computing, such as cloud computing. The network 530, in some cases with the aid of the computer system 501, can implement a peer-to-peer network, which may enable devices coupled to the computer system 501 to behave as a client or a server.

The CPU 505 can execute a sequence of machine-readable instructions, which can be embodied in a program or software. The instructions may be stored in a memory location, such as the memory 510. The instructions can be directed to the CPU 505, which can subsequently program or otherwise configure the CPU 505 to implement methods of the present disclosure. Examples of operations performed by the CPU 505 can include fetch, decode, execute, and writeback.

The CPU 505 can be part of a circuit, such as an integrated circuit. One or more other components of the system 501 can be included in the circuit. In some cases, the circuit is an application-specific integrated circuit (ASIC).

The storage unit 515 can store files, such as drivers, libraries, and saved programs. The storage unit 515 can store user data, e.g., user preferences and user programs. The computer system 501, in some cases, can include one or more additional data storage units that are external to the computer system 501, such as located on a remote server that is in communication with the computer system 501 through an intranet or the Internet.

The computer system 501 can communicate with one or more remote computer systems through the network 530. For instance, the computer system 501 can communicate with a remote computer system of a user (e.g., a personal health device, laptop, monitoring device, or any other device commonly used by a health practitioner). Examples of remote computer systems include personal computers (e.g., portable PC), slate or tablet PC's (e.g., Apple® iPad, Samsung® Galaxy Tab), telephones, smartphones (e.g., Apple® iPhone, Android-enabled device, Blackberry®), or personal digital assistants. The user can access the computer system 501 via the network 530.

Methods as described herein can be implemented by way of machine (e.g., computer processor) executable code stored on an electronic storage location of the computer system 501, such as, for example, on the memory 510 or electronic storage unit 515. The machine executable or machine-readable code can be provided in the form of software. During use, the code can be executed by the processor 505. In some cases, the code can be retrieved from the storage unit 515 and stored on the memory 510 for ready access by the processor 505. In some situations, the electronic storage unit 515 can be precluded, and machine-executable instructions are stored in memory 510.

The code can be pre-compiled and configured for use with a machine having a processor adapted to execute the code, or can be compiled during runtime. The code can be supplied in a programming language that can be selected to enable the code to execute in a pre-compiled or as-compiled fashion.

Aspects of the systems and methods provided herein, such as the computer system 501, can be embodied in programming. Various aspects of the technology may be thought of as “products” or “articles of manufacture,” typically in the form of machine (or processor) executable code and/or associated data that is carried on or embodied in a type of machine-readable medium.

Machine-executable code can be stored on an electronic storage unit, such as memory (e.g., read-only memory, random-access memory, flash memory) or a hard disk. “Storage” type media can include any or all of the tangible memory of the computers, processors, or the like, or associated modules thereof, such as various semiconductor memories, tape drives, disk drives, and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer into the computer platform of an application server. Thus, another type of media that may bear the software elements includes optical, electrical, and electromagnetic waves, such as those used across physical interfaces between local devices, through wired and optical landline networks, and over various air-links. The physical elements that carry such waves, such as wired or wireless links, optical links, or the like, may also be considered as media bearing the software. As used herein, unless restricted to non-transitory, tangible “storage” media, terms such as computer or machine “readable medium” refer to any medium that participates in providing instructions to a processor for execution.

Hence, a machine-readable medium, such as computer-executable code, may take many forms, including but not limited to, a tangible storage medium, a carrier wave medium, or a physical transmission medium. Non-volatile storage media include, for example, optical or magnetic disks, such as any of the storage devices in any computer(s) or the like, such as may be used to implement the databases, etc., shown in the drawings. Volatile storage media include dynamic memory, such as the main memory of a computer platform. Tangible transmission media include coaxial cables; copper wire and fiber optics, including the wires that comprise a bus within a computer system. Carrier-wave transmission media may take the form of electric or electromagnetic signals, or acoustic or light waves such as those generated during radio frequency (RF) and infrared (IR) data communications. Common forms of computer-readable media therefore include for example: a floppy disk, a flexible disk, hard disk, magnetic tape, any other magnetic medium, a CD-ROM, DVD or DVD-ROM, any other optical medium, punch cards paper tape, any other physical storage medium with patterns of holes, a RAM, a ROM, a PROM and EPROM, a FLASH-EPROM, any other memory chip or cartridge, a carrier wave transporting data or instructions, cables or links transporting such a carrier wave, or any other medium from which a computer may read programming code and/or data. Many of these forms of computer-readable media may be involved in carrying one or more sequences of one or more instructions to a processor for execution.

The computer system 501 can include or be in communication with an electronic display 535 that comprises a user interface (UI) 540 for providing. Examples of UI's include, without limitation, a graphical user interface (GUI) and a web-based user interface.

Methods and systems of the present disclosure can be implemented by way of one or more algorithms. An algorithm can be implemented by way of software upon execution by the central processing unit 505.

While preferred embodiments of the present disclosure have been shown and described herein, such embodiments are provided by way of example only. Numerous variations, changes, and substitutions can occur without departing from the disclosure. It can be understood that various alternatives to the embodiments of the present disclosure may be employed in practicing the present disclosure. It is intended that the following claims define the scope of the present disclosure and that methods and structures within the scope of these claims and their equivalents be covered thereby.

1. An acoustic device comprising:
a piezoelectric substrate; and
a multi-layer metallic stack comprising a bonding layer, a conduction layer, and a cap layer, wherein:
the bonding layer is configured to facilitate bonding of the conduction layer to the piezoelectric substrate, and
the cap layer is configured to facilitate soldering of the acoustic device to an electrical circuit.

2. The acoustic device of claim 1, wherein:
the multi-layer metallic stack further comprises a barrier layer, positioned between the conduction layer and the cap layer, and configured to prevent diffusion between the conduction layer and the cap layer, and
the barrier layer comprises tungsten, titanium, nickel, nickel-phosphorous, vanadium, chromium, molybdenum, or any combination thereof.

3. The acoustic device of claim 2, wherein the barrier layer has a thickness of 0.5-20 nm.

4. The acoustic device of claim 1, wherein the conduction layer is between the bonding layer and the cap layer.

5. The acoustic device of claim 1, wherein the bonding layer is located closer to the piezoelectric substrate than the cap layer.

6. The acoustic device of claim 1, wherein the piezoelectric substrate comprises lithium niobate.

7. The acoustic device of claim 6, wherein the lithium niobate comprises chemically reduced lithium niobate.

8. The acoustic device of claim 1, wherein the conduction layer is non-oxidized.

9. The acoustic device of claim 1, wherein:
the conduction layer comprises aluminum or an aluminum-based alloy,
the bonding layer comprises titanium, chromium, or a tungsten-based alloy, and
the cap layer comprises copper, nickel, gold, tin, or an alloy comprising any combination thereof.

10. The acoustic device of claim 1, wherein:
the conduction layer is thicker than the bonding layer or the cap layer, and
the cap layer is thicker than the bonding layer.

11. The acoustic device of claim 1, wherein:
the bonding layer is 1-5 nm thick,
the conduction layer is 300-2000 nm thick, and
the cap layer is 30-150 nm thick,
the piezoelectric substrate is 200-1000 micrometers thick.

12. The acoustic device of claim 1, further comprising one or more solder interconnects configured to electromechanically couple the acoustic device to the electrical circuit and comprises a lead-free solder.

13. The acoustic device of claim 12, wherein the lead-free solder comprises tin and at least one of copper, silver, nickel, zinc, bismuth, or antimony.

14. The acoustic device of claim 12, wherein the lead-free solder has a melting temperature of 130-400°C.

15. The acoustic device of claim 12, wherein the one or more solder interconnects have a height of 25-75 micrometers.

16. The acoustic device of claim 1, wherein the bonding layer comprises a reactive metal configured to form a chemical bond with polar atoms on a surface of the piezoelectric substrate.

17. The acoustic device of claim 1, wherein the cap layer is configured to prevent formation of an oxide layer on the conduction layer.

18. The acoustic device of claim 17, wherein the conduction layer comprises aluminum or zinc, and wherein the cap layer is configured to prevent formation of aluminum oxide or zinc oxide on the conduction layer.

19. The acoustic device of claim 1, wherein the acoustic device is configured to generate acoustic waves having one or more waveforms selected from a continuous sine wave, a square wave, or a triangular wave.

20. The acoustic device of claim 1, wherein the piezoelectric substrate comprises zinc oxide or aluminum nitride deposited on a secondary substrate comprising silicon or polyamide.
